(19) United States
(12) Patent Application Publication
(10) Pub. No.: US 2024/0096792 A1
(43) Pub. Date: Mar. 21, 2024

(54) SEMICONDUCTOR MODULE AND SEMICONDUCTOR DEVICE

(71) Applicant: Murata Manufacturing Co., Ltd., Kyoto-fu (JP)

(72) Inventors: Satoshi GOTO, Nagaokakyo-shi (JP); Masao KONDO, Nagaokakyo-shi (JP); Shigeki KOYA, Nagaokakyo-shi (JP); Takayuki TSUTSUI, Nagaokakyo-shi (JP)

(73) Assignee: Murata Manufacturing Co., Ltd., Kyoto-fu (JP)

(21) Appl. No.: 18/522,110

(22) Filed: Nov. 28, 2023

Related U.S. Application Data
(63) Continuation of application No. PCT/JP2022/022185, filed on May 31, 2022.

(30) Foreign Application Priority Data
Jun. 11, 2021 (JP) 2021-098095

(51) Int. Cl. H01L 23/528; H01L 23/00; H01L 23/64; H01L 25/065

(52) U.S. Cl. CPC H01L 23/528; H01L 23/64; H01L 24/32; H01L 24/48; H01L 24/73; H01L 25/0657; H01L 24/16; H01L 2224/16225; H01L 2224/32227; H01L 2224/32238; H01L 2224/48229; H01L 2224/73265; H01L 2225/0651; H01L 2225/06517; H01L 2225/06541; H01L 2924/19011

(57) ABSTRACT

A semiconductor module comprises a first member including a semiconductor substrate made of a compound semiconductor and a first electronic circuit on the semiconductor substrate is mounted on a mounting surface of a module substrate, and a second member including a semiconductor layer formed of a single semiconductor thinner than the semiconductor substrate of the first member and a second electronic circuit on the semiconductor layer is bonded to an upper surface of the first member. First and second pads are respectively connected to the first electronic circuit on the first member and the second electronic circuit on the second member. A first wire connects the first pad and a substrate side pad. A second wire connects the second pad and a substrate side pad. An inter-member connection wire made of a conductor film on the first and second members connects the first and second electronic circuits.

### CROSS-REFERENCE TO RELATED APPLICATIONS

This application claims benefit of priority to International Patent Application No. PCT/JP2022/022185, filed May 31, 2022, and to Japanese Patent Application No. 2021-098095, filed Jun. 11, 2021, the entire contents of each are incorporated herein by reference.

### BACKGROUND

### Technical Field

The present disclosure relates to a semiconductor module and a semiconductor device.

### Background Art

A semiconductor device is known in which a silicon die in which a control circuit is formed is stacked on an HBT die in which a high frequency power amplifier circuit including a heterojunction bipolar transistor (HBT) is formed as described, for example, in United States Patent Application Publication No. 2015/0303971. The semiconductor element is face-up mounted on a module substrate. Connection is made between the HBT die and the silicon die, between the HBT die and the module substrate, and between the silicon die and the module substrate by wire bonding. Since the silicon die is stacked on the HBT die, an area occupied by the semiconductor element on a surface of the module substrate is reduced.

### SUMMARY

By stacking a silicon die on an HBT die, an exclusive area on a mounting surface of a module substrate can be reduced, but a dimension in a height direction increases. In a semiconductor module in which a semiconductor device is mounted on a module substrate, it is desired to reduce a dimension in a thickness direction. It is desirable to reduce a height of the semiconductor device in order to reduce the dimension of the semiconductor module in the thickness direction.

Accordingly, the present disclosure provides a semiconductor module and a semiconductor device that can reduce a height of the semiconductor device and reduce a dimension in a thickness direction.

According to an aspect of the present disclosure, there is provided a semiconductor module including a module substrate that has a plurality of substrate side pads disposed on a surface; a first member that is mounted on a mounting surface of the module substrate, and includes a semiconductor substrate made of a compound semiconductor and a first electronic circuit provided on the semiconductor substrate; and a second member that is bonded to an upper surface of the first member, and includes a semiconductor layer made of a single semiconductor thinner than the semiconductor substrate and a second electronic circuit provided on the semiconductor layer. The semiconductor module also includes a first pad that is disposed on the first member and is connected to the first electronic circuit; a second pad that is disposed on the second member and is connected to the second electronic circuit; a first wire that connects the first pad and one of the plurality of substrate side pads to each other; a second wire that connects the second pad and one of the plurality of substrate side pads to each other; and an inter-member connection wire made of a conductor film that is disposed on the first member and the second member and connects the first electronic circuit and the second electronic circuit to each other.

Since a second member is thinner than a first member, it is possible to reduce a height of a semiconductor device as compared with a configuration in which the thicknesses of the first member and the second member are approximately the same.

### BRIEF DESCRIPTION OF THE DRAWINGS

FIG. 1 is a cross-sectional view of a semiconductor device according to a first embodiment;

FIG. 2 is a cross-sectional view of a semiconductor module according to the first embodiment;

FIG. 3 is an equivalent circuit diagram and a block diagram of a first electronic circuit and a second electronic circuit of the semiconductor device;

FIG. 4 is a block diagram of the semiconductor module according to the first embodiment, focusing on a transmission and reception function of a high-frequency signal;

FIG. 5 is a diagram illustrating a positional relationship between a terminal provided on a first member and a second member and a substrate side pad provided on a module substrate (FIG. 2) in a plan view;

FIGS. 6A and 6B are a cross-sectional view and a plan view at an intermediate stage of manufacturing of the semiconductor device according to the first embodiment, respectively;

FIGS. 7A and 7B are a cross-sectional view and a plan view at the intermediate stage of the manufacturing of the semiconductor device according to the first embodiment, respectively;

FIGS. 8A and 8B are a cross-sectional view and a plan view at the intermediate stage of the manufacturing of the semiconductor device according to the first embodiment, respectively;

FIGS. 9A and 9B are a cross-sectional view and a plan view at an intermediate stage of manufacturing of the semiconductor device according to a first embodiment, respectively;

FIGS. 10A to 10E are cross-sectional views at the intermediate stage of manufacturing of the semiconductor device according to the first embodiment;

FIGS. 11A and 11B are a cross-sectional view and a plan view at an intermediate stage of manufacturing of a semiconductor device according to a second embodiment, respectively;

FIGS. 12A and 12B are a cross-sectional view and a plan view at the intermediate stage of the manufacturing of the semiconductor device according to the second embodiment, respectively;

FIG. 13 is a cross-sectional view of a semiconductor device according to a third embodiment;

FIG. 14 is a cross-sectional view of a semiconductor device according to a modification example of the third embodiment;

FIG. 15 is a diagram illustrating a positional relationship between a terminal provided on a first member and a second member of a semiconductor device according to a fourth embodiment and the substrate side pad provided on the module substrate (FIG. 2) in a plan view;

FIG. 16 is a cross-sectional view of the semiconductor device in a region where a cross wire and a power supply terminal Vbat2 overlap each other in a plan view;

FIG. 17 is a diagram illustrating a positional relationship between a terminal provided on a first member and a second member of a semiconductor device according to a fifth embodiment and the substrate side pad provided on the module substrate (FIG. 2) in a plan view;

FIG. 18 is a cross-sectional view of the semiconductor device focusing on a region where a shield film is disposed;

FIG. 19 is a diagram illustrating a positional relationship between a terminal provided on a first member and a second member of a semiconductor device according to a sixth embodiment and the substrate side pad provided on the module substrate (FIG. 2) in a plan view;

FIG. 20 is a diagram illustrating a positional relationship between a terminal provided on a first member and a second member of a semiconductor device according to a modification example of the sixth embodiment and the substrate side pad provided on the module substrate (FIG. 2) in a plan view;

FIG. 21 is a cross-sectional view of a semiconductor device according to a seventh embodiment;

FIG. 22 is a cross-sectional view of a semiconductor device according to an eighth embodiment; and

FIGS. 23A to 23E are cross-sectional views at an intermediate stage of manufacturing a semiconductor device according to the eighth embodiment.

### DETAILED DESCRIPTION

### First Embodiment

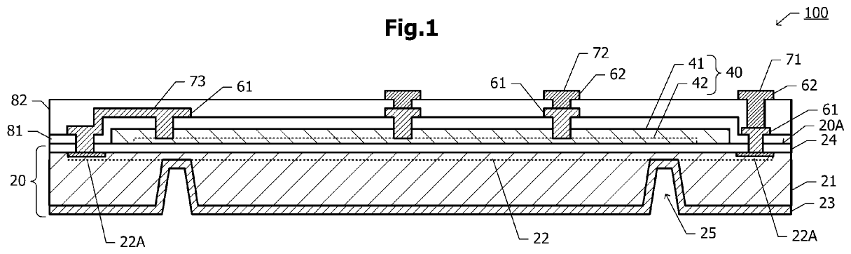

A semiconductor device and a semiconductor module according to a first embodiment will be described with reference to FIGS. 1 to 10E.

FIG. 1 is a cross-sectional view of a semiconductor device 100 according to a first embodiment. The semiconductor device 100 according to the first embodiment includes a first member 20, a second member 40 bonded to one surface (upper surface) of the first member 20, and a wiring structure disposed on the first member 20 and the second member 40.

Next, a configuration of the first member 20 will be described. A first electronic circuit 22 is formed on a semiconductor substrate 21 made of a compound semiconductor such as GaAs. The first electronic circuit 22 includes a plurality of heterojunction bipolar transistors, a plurality of passive elements, a plurality of conductor patterns 22A, multilayer wiring, and the like. For example, Au is used for the conductor pattern 22A. In FIG. 1, a region where the first electronic circuit 22 is disposed is indicated by a broken line. An insulating film 24 is disposed on the entire upper surface of the semiconductor substrate 21. For example, silicon nitride is used as the insulating film 24. A surface of the insulating film 24 corresponds to an upper surface 20A of the first member 20.

A plurality of back side vias 25 reaching the first electronic circuit 22 from a lower surface of the semiconductor substrate 21 are formed. A back surface conductor film 23 of Cu or the like is formed so as to cover a side surface and a bottom surface of the back side via 25 and a lower surface of the semiconductor substrate 21. The back surface conductor film 23 is connected to a ground conductor in the first electronic circuit 22.

The second member 40 includes a thin film semiconductor layer 41 made of a single semiconductor such as Si and a second electronic circuit 42 provided on the semiconductor layer 41, and is bonded to the upper surface 20A of the first member 20. The semiconductor layer 41 is thinner than the semiconductor substrate 21 of the first member 20. The second member 40 is smaller than the first member 20 in a plan view, and the upper surface 20A of the first member 20 includes a picture frame-shaped region to which the second member 40 is not bonded in a plan view.

The second electronic circuit 42 is provided on a surface of the semiconductor layer 41 that faces the first member 20. The second electronic circuit 42 includes a switching transistor such as a MOS transistor, a passive element, a multilayer wiring structure, and the like. The outermost surface of the multilayer wiring structure is bonded to the upper surface 20A of the first member 20 in surface contact. The surface of the second member 40 bonded to the first member 20 is referred to as a bonding surface.

A first common insulating film 81 made of polyimide or the like is disposed so as to cover the upper surface 20A of the first member 20 and the surface of the second member 40. A plurality of contact holes are provided at predetermined positions in the first common insulating film 81, the semiconductor layer 41, and the insulating film 24. Some contact holes reach from an upper surface of the first common insulating film 81 to a surface opposite to the bonding surface of the second member 40, further extend the semiconductor layer 41 in the thickness direction, and reach a conductor pattern included in the second electronic circuit 42. Some other contact holes penetrate the first common insulating film 81 and the insulating film 24 and reach the conductor pattern 22A. A plurality of first-layer conductor patterns 61 are disposed on the first common insulating film 81. For example, Cu is used for the first-layer conductor pattern 61. The conductor layer in which the first-layer conductor pattern 61 is disposed is also called a rewiring layer.

Some of the first-layer conductor patterns 61 are connected to the conductor pattern 22A through contact holes provided in the first common insulating film 81 and the insulating film 24. In addition, some other first-layer conductor patterns 61 are connected to the second electronic circuit 42 through contact holes provided in the first common insulating film 81 and the semiconductor layer 41. Further, some other first-layer conductor patterns 61 are disposed so as to straddle the edge of the second member 40 and intersect the edge of the second member 40 in a plan view. The conductor pattern 61 is connected to the second electronic circuit 42 at a portion that overlaps the second member 40 in a plan view, and is connected to the conductor pattern 22A at a portion where the second member 40 is not disposed. The conductor pattern 61 straddling the edge of the second member 40 connects the first electronic circuit 22 and the second electronic circuit 42. The conductor pattern 61 that connects the first electronic circuit 22 and the second electronic circuit 42 is referred to as an inter-member connection wire 73. The inter-member connection wire 73 is also called a rewire.

A second common insulating film 82 is disposed on the first common insulating film 81 so as to cover the first-layer conductor pattern 61. A plurality of contact holes are provided at predetermined positions in the second common insulating film 82. A plurality of second-layer conductor patterns 62 are disposed on the second common insulating film 82. For example, Cu is used for the second-layer conductor pattern 62. The second-layer conductor pattern 62 is connected to the first-layer conductor pattern 61 through a contact hole provided in the second common insulating film 82.

Some second-layer conductor patterns 62 are disposed in regions where the second member 40 is not disposed in a plan view, and are connected to the conductor pattern 22A, that is, the first electronic circuit 22, with the first-layer conductor pattern 61 interposed therebetween. The second-layer conductor pattern 62 connected to the first electronic circuit 22 is used as a first pad 71 for wire bonding for connecting the first electronic circuit 22 and the module substrate. Some other second-layer conductor patterns 62 are disposed inside the second member 40 in a plan view, and are connected to the second electronic circuit 42 with the first-layer conductor pattern 61 interposed therebetween. The second-layer conductor pattern 62 connected to the second electronic circuit 42 is used as a second pad 72 for wire bonding for connecting the second electronic circuit 42 and the module substrate. The first-layer conductor pattern 61 that connects the second pad 72 and the second electronic circuit 42 is used as a via conductor that extends in the thickness direction of the semiconductor layer 41 and connects the lower layer conductor and the upper layer conductor.

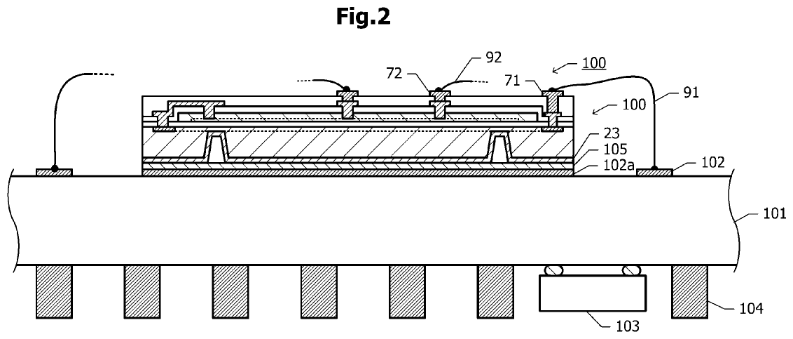

FIG. 2 is a cross-sectional view of the semiconductor module according to the first embodiment. A plurality of substrate side pads 102 are disposed on one surface (hereinafter, referred to as an upper surface) of a module substrate 101. At least one of the plurality of substrate side pads 102 is a ground pad 102a. As the module substrate 101, a ceramic substrate having a multilayer wiring structure, a printed substrate, or the like is used. A low noise amplifier 103 is mounted on a surface (hereinafter, referred to as a lower surface) opposite to the upper surface of the module substrate 101, and a plurality of connection terminals 104 are provided.

The semiconductor device 100 is face-up mounted on the module substrate 101 such that the surface on which the first pad 71 and the second pad 72 are disposed faces the side opposite to the module substrate 101. Specifically, the back surface conductor film 23 of the semiconductor device 100 is mechanically fixed to the ground pad 102a and electrically connected to the ground pad 102a by a solder layer 105.

Each of the first pads 71 of the semiconductor device 100 and the plurality of substrate side pads 102 are connected to each other by a first wire 91. Each of the second pads 72 of the semiconductor device 100 and the substrate side pad 102 are connected to each other by a second wire 92. The first wire 91 and the second wire 92 are connected to each pad by wire bonding technology.

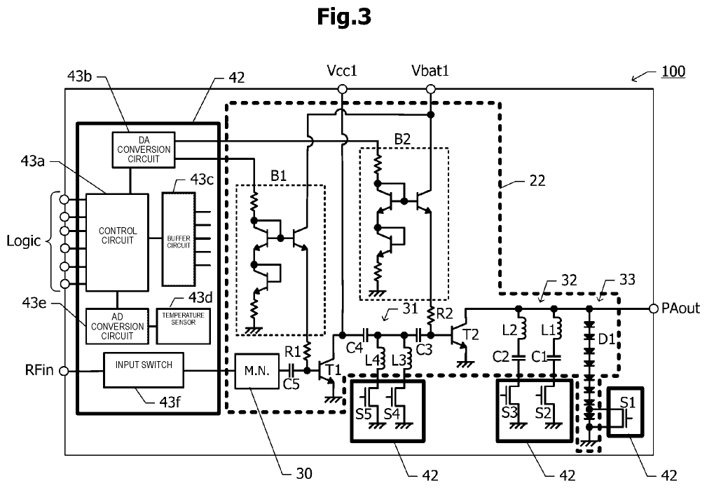

FIG. 3 is an equivalent circuit diagram and a block diagram of the first electronic circuit 22 and the second electronic circuit 42 of the semiconductor device 100.

The first electronic circuit 22 is a high frequency power amplifier circuit having a two-stage configuration, and includes a driver stage transistor T1 and an output stage transistor T2. The driver stage transistor T1 and the output stage transistor T2 are respectively configured with a plurality of transistor cells connected in parallel to each other. The first electronic circuit 22 further includes an input side impedance matching circuit 30, an inter-stage impedance matching circuit 31, a harmonic wave termination circuit 32, a protection circuit 33, ballast resistance elements R1 and R2, and a capacitor C5.

A base of the driver stage transistor T1 is connected to the first bias circuit B1 with the ballast resistance element R1 interposed therebetween. The ballast resistance element R1 is provided for each of the plurality of transistor cells constituting the driver stage transistor T1. A base of the output stage transistor T2 is connected to the second bias circuit B2 with the ballast resistance element R2 interposed therebetween. The ballast resistance element R2 is provided for each of the plurality of transistor cells constituting the output stage transistor T2. The first bias circuit B1 and the second bias circuit B2 are connected to a power supply terminal Vbat1.

Emitters of the driver stage transistor T1 and the output stage transistor T2 are grounded. A collector of the driver stage transistor T1 is connected to a collector power supply terminal Vcc1. A collector of the output stage transistor T2 is connected to an amplifier output terminal PAout.

The second electronic circuit 42 includes a control circuit 43a, a DA conversion circuit 43b, a buffer circuit 43c, a temperature sensor 43d, an AD conversion circuit 43e, an input switch 43f, and MOS transistors S1, S2, S3, S4, and S5.

The inter-stage impedance matching circuit 31 includes capacitors C3 and C4 and inductors L3 and L4. The collector of the driver stage transistor T1 is connected to the base of the output stage transistor T2 with a series connection circuit of the capacitor C4 and the capacitor C3 interposed therebetween. One end portion of each of the inductor L3 and the inductor L4 is connected to a portion where the capacitor C3 and the capacitor C4 are connected to each other. The other end portions of each of the inductor L3 and the inductor L4 are grounded with the MOS transistors S4 and S5 interposed therebetween, respectively. The capacitor C3 is provided for each of the plurality of transistor cells constituting the output stage transistor T2.

The inductances of the inductors L3 and L4 are different from each other. The connection between the inductor L3 and the MOS transistor S4 and the connection between the inductor L4 and the MOS transistor S5 are realized by the inter-member connection wire 73 (FIG. 1). By switching on and off of the MOS transistors S4 and S5 or by turning on both of the MOS transistors S4 and S5, the impedance matching can be optimized according to an operating frequency band. A circuit having another circuit configuration including a plurality of passive elements may be employed as the inter-stage impedance matching circuit 31.

The harmonic wave termination circuit 32 includes a series resonance circuit configured with the inductor L1 and the capacitor C1 and a series resonance circuit configured with the inductor L2 and the capacitor C2. One end portion of each of the two series resonance circuits is connected to the collector of the output stage transistor T2. The other end portion of the series resonance circuit configured with the inductor L1 and the capacitor C1 and the other end portion of the series resonance circuit configured with the inductor L2 and the capacitor C2 are grounded with MOS transistors S2 and S3 interposed therebetween, respectively.

The connection between the series resonance circuit configured with the inductor L1 and the capacitor C1 and the MOS transistor S2 and the connection between the series resonance circuit configured with the inductor L2 and the capacitor C2 and the MOS transistor S3 are realized by the inter-member connection wire 73 (FIG. 1). The resonant frequency of the series resonance circuit configured with the inductor L1 and the capacitor C1 and the resonant frequency of the series resonance circuit configured with the inductor L2 and the capacitor C2 are different from each other. By switching on and off of the MOS transistors S2 and S3 or by turning on both of the MOS transistors S2 and S3, the harmonic wave termination circuit can be optimized according to the operating frequency band.

The protection circuit 33 includes a plurality of diodes D1 connected in multistage between the collector of the output stage transistor T2 and the ground. The plurality of diodes D1 are connected such that a direction from the collector of the output stage transistor T2 to the ground is a forward direction. The MOS transistor S1 is connected in parallel to at least one diode D1 of the plurality of diodes D1 constituting the protection circuit 33.

The connection between the diode D1 and the MOS transistor S1 is realized by two inter-member connection wires 73 (FIG. 1). By switching on and off of the MOS transistor S1, the effective number of stages of the diode D1 constituting the protection circuit can be switched.

The inter-stage impedance matching circuit 31, the harmonic wave termination circuit 32, and the protection circuit 33 can be controlled circuits whose operating states change by switching on and off of the MOS transistors S1, S2, S3, S4, and S5.

The high-frequency signal input to an input terminal RFin is input to the base of the driver stage transistor T1 with the input switch 43f, the input side impedance matching circuit 30, and the capacitor C5 interposed therebetween. The input switch 43f performs path selection of a high-frequency signal or switching of an attenuator. The capacitor C5 is provided for each of a plurality of transistor cells constituting the driver stage transistor T1. The high-frequency signal amplified by the driver stage transistor T1 is input to the base of the output stage transistor T2 with the inter-stage impedance matching circuit 31 interposed therebetween. The high-frequency signal amplified by the output stage transistor T2 is output from the amplifier output terminal PAout.

The temperature sensor 43d measures an environmental temperature. The measurement result is converted into a digital signal by the AD conversion circuit 43e and input to the control circuit 43a. The control circuit 43a controls the operation of the first electronic circuit 22 based on control signals input from a plurality of logic terminals Logic and a measured value of the temperature by the temperature sensor 43d. In addition to the temperature sensor 43d, a temperature dependent element whose characteristics change according to the temperature may be used. In this case, the control circuit 43a controls the operation of the first electronic circuit 22 in accordance with the change in the characteristics of the temperature dependent element.

Specifically, a bias control signal output from the control circuit 43a is converted into an analog signal by the DA conversion circuit 43b, and is input to the first bias circuit B1 and the second bias circuit B2. The connection between the DA conversion circuit 43b and the first bias circuit B1 and the connection between the DA conversion circuit 43b and the second bias circuit B2 are realized by the inter-member connection wire 73 (FIG. 1), respectively. The first bias circuit B1 and the second bias circuit B2 supply base biases to the driver stage transistor T1 and the output stage transistor T2, respectively, in response to the bias control signal. As a result, the base bias is appropriately adjusted according to the operating frequency and the environmental temperature.

Further, the control circuit 43a controls the on and off of the MOS transistors S1, S2, S3, S4, and S5 with the buffer circuit 43c interposed therebetween. Specifically, the control circuit 43a turns on one of the MOS transistors S4 and S5 connected to the inter-stage impedance matching circuit 31 and one of the MOS transistors S2 and S3 connected to the harmonic wave termination circuit 32, according to the operating frequency band. As a result, the impedance matching between the stages is optimized, and the harmonic waves included in the high-frequency signal output from the output stage transistor T2 are appropriately suppressed.

Further, the control circuit 43a controls the on and off of the MOS transistor S1 according to the environmental temperature measured by the temperature sensor 43d. Generally, when the environmental temperature decreases, a breakdown withstand voltage of the output stage transistor T2 decreases and a forward voltage of the diode D1 increases. Therefore, a protection function of the protection circuit 33 deteriorates. When the environmental temperature becomes equal to or less than a predetermined determination threshold value, the MOS transistor S1 is turned on. Accordingly, the effective number of stages of the diode D1 constituting the protection circuit 33 is reduced. As a result, the deterioration in the protection function of the protection circuit 33 is suppressed.

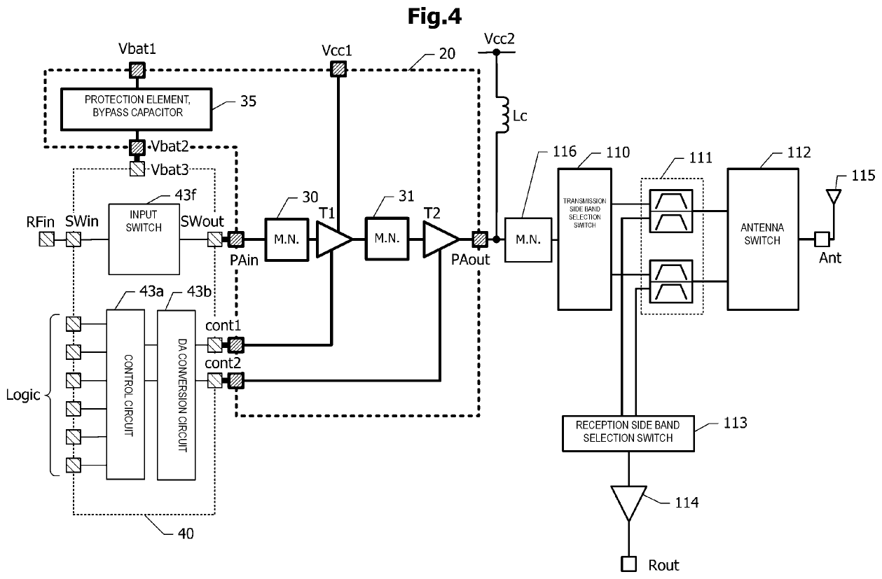

FIG. 4 is a block diagram of the semiconductor module according to the first embodiment, focusing on a transmission and reception function of the high-frequency signal. In FIG. 4, the terminal provided on the first member is indicated by a square hatched upward to the right with a relatively high density, and the terminal provided on the second member 40 is indicated by a square hatched downward to the right with a relatively low density. Further, a terminal (substrate side pad 102 in FIG. 2) provided on the module substrate 101 (FIG. 2) is indicated by an open square.

The terminal provided on the first member 20 corresponds to the first pad 71 (FIG. 1) or the end portion of the inter-member connection wire 73 (FIG. 1) on the first member 20 side. The terminal provided on the second member 40 corresponds to the second pad (FIG. 1) or the end portion of the inter-member connection wire 73 on the second member 40 side.

The semiconductor module includes the first member 20 and the second member 40 of the semiconductor device 100, an output side impedance matching circuit 116, a transmission side band selection switch 110, a plurality of duplexers 111, an antenna switch 112, a reception side band selection switch 113, and a low noise amplifier 114. The output side impedance matching circuit 116, the transmission side band selection switch 110, the duplexer 111, the antenna switch 112, the reception side band selection switch 113, and the low noise amplifier 114 are mounted on the module substrate 101.

A high-frequency signal is input from the input terminal RFin. The high-frequency signal input to the input terminal RF in is input to the input switch 43f of the second member 40 with an input terminal SWin interposed therebetween, and the high-frequency signal that passes through the input switch 43f is output from an output terminal SWout.

The high-frequency signal output from the output terminal SWout is input to an amplifier input terminal PAin of the first member 20. The high-frequency signal input to the amplifier input terminal PAin is output from an amplifier output terminal PAout through the input side impedance matching circuit 30, the driver stage transistor T1, the inter-stage impedance matching circuit 31, and the output stage transistor T2.

The amplifier output terminal PAout is connected to a collector power supply Vcc2 of the module substrate 101 with a choke coil Lc interposed therebetween. The collector power supply Vcc2 is supplied to the collector of the output stage transistor T2 with the choke coil Lc interposed therebetween.

The high-frequency signal output from the amplifier output terminal PAout is input to the transmission side band selection switch 110 with the output side impedance matching circuit 116 of the module substrate 101 interposed therebetween (FIG. 2). A plurality of output ports of the band selection switch 110 are connected to a plurality of duplexers 111 having different passage bands. The band selection switch 110 selects one from the plurality of duplexers 111, and the transmission signal is input to the transmission signal input port of the selected duplexer 111.

The transmission and reception common ports of the plurality of duplexers 111 are connected to the antenna switch 112. The antenna switch 112 selects one from the plurality of duplexers 111. The transmission signal that passes through the duplexer 111 is output from an antenna terminal Ant through the antenna switch 112. An antenna 115 is connected to the antenna terminal Ant.

The reception side band selection switch 113 is connected to received signal output ports of the plurality of duplexers 111. The received signal received at the antenna 115 is input to the reception side band selection switch 113 through the antenna terminal Ant, the antenna switch 112, and the duplexer 111. The received signal that passes through the band selection switch 113 is amplified by the low noise amplifier 114 and output from a received signal output terminal Rout.

The control signals input to the plurality of logic terminals Logic of the second member 40 are input to the control circuit 43a. The control circuit 43a outputs bias control signals from bias control terminals cont1 and cont2 of the second member 40 with the DA conversion circuit 43b interposed therebetween. The bias control terminals cont1 and cont2 of the second member 40 are connected to the bias control terminals cont1 and cont2 of the first member 20, respectively.

The bias control terminals cont1 and cont2 of the first member 20 are connected to the first bias circuit B1 and the second bias circuit B2 (FIG. 3) of the driver stage transistor T1 and the output stage transistor T2, respectively.

The collector power supply terminal Vcc1 of the first member 20 is connected to the collector of the driver stage transistor T1. Power is supplied to the collector of the driver stage transistor T1 with the choke coil mounted on the module substrate 101 (FIG. 2) and the collector power supply terminal Vcc1 interposed therebetween. A bypass capacitor connected to the collector power supply terminal Vcc1 is mounted on the module substrate 101 (FIG. 2).

The power supply terminal Vbat1 of the first member 20 is connected to the power supply terminal Vbat2 with a protection element provided on the first member 20 and the bypass capacitor 35 interposed therebetween. The power supply terminal Vbat2 of the first member 20 is connected to the power supply terminal Vbat3 of the second member 40. In FIG. 3, the description of the protection element and the bypass capacitor 35 is omitted.

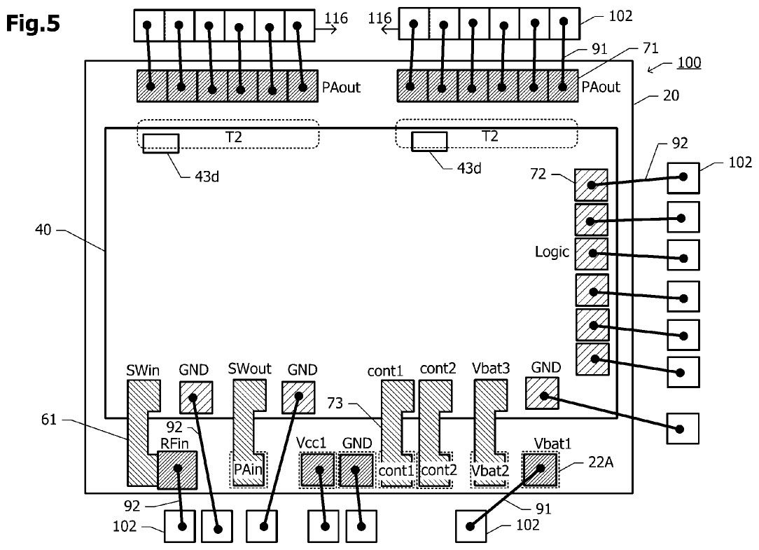

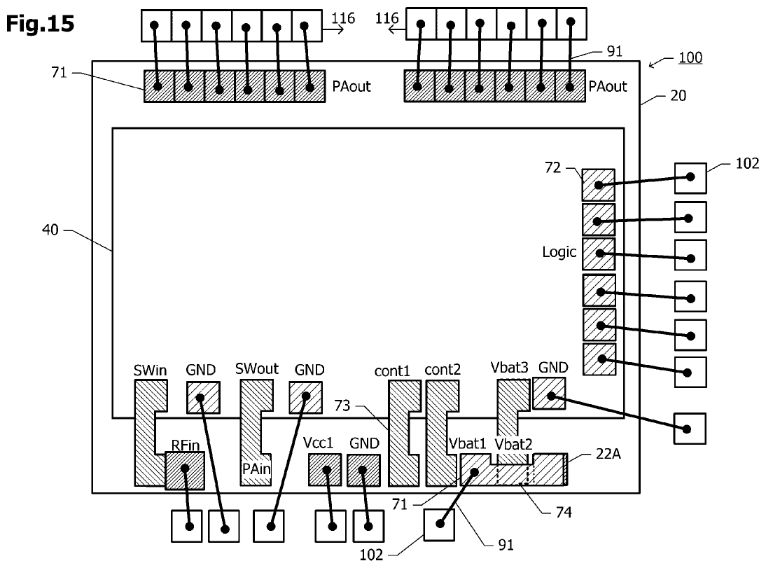

FIG. 5 is a diagram illustrating a positional relationship between the terminals provided on the first member 20 and the second member 40 and the substrate side pad 102 provided on the module substrate 101 (FIG. 2) in a plan view. In FIG. 5, the first pad 71 (FIG. 1) and the input terminal RFin disposed on an outer side portion of the second member 40 are indicated by relatively high-density hatching upward to the right, and the second pad 72 (FIG. 2) disposed on the second member 40 is indicated by relatively low-density hatching upward to the right. The first-layer conductor pattern 61 that intersects the edge of the second member 40, for example, the inter-member connection wire 73 (FIG. 1), or the like is marked with medium-density hatching downward to the right. A plurality of substrate side pads 102 provided on the module substrate 101 (FIG. 2) are represented by white squares. The same applies to FIGS. 15, 17, 19, and 20 which will be described later.

The second member 40 is smaller than the first member 20 in a plan view. The collector power supply terminal Vcc1, the ground terminal GND, the power supply terminal Vbat1, the amplifier output terminal PAout, and the input terminal RFin configured with the second-layer conductor pattern 62 (FIG. 1) are disposed in a region of the first member 20 that does not overlap the second member 40 in a plan view. The amplifier output terminal PAout is configured with a plurality of first pads 71 disposed in a row or with a first pad 71 long in one direction. The terminals configured with the first pad 71 substantially overlap the conductor pattern 22A of the first electronic circuit 22 in a plan view. In FIG. 5, the conductor pattern 22A is indicated by a broken line. The collector power supply terminal Vcc1, the ground terminal GND, the power supply terminal Vbat1, and the amplifier output terminal PAout are respectively connected to the substrate side pad 102 by the first wire 91. For example, the substrate side pad 102 connected to the amplifier output terminal PAout is connected to the output side impedance matching circuit 116 (FIG. 4) and the choke coil Lc (FIG. 4).

In a plan view, the plurality of logic terminals Logic and the plurality of ground terminals GND configured with the second pads 72 (FIG. 2), and the input terminal SWin, the output terminal SWout, the bias control terminal cont1 and cont2, and the power supply terminal Vbat3 configured with the first-layer conductor pattern 61 (FIG. 1) are disposed in the vicinity of the edge of the second member 40. The plurality of logic terminals Logic and the plurality of ground terminals GND are respectively connected to the substrate side pad 102 with the second wires 92 interposed between. The input terminal SWin is extracted to the outer side portion of the second member 40 in a plan view by the first-layer conductor pattern 61, and is connected to the input terminal RFin configured with the second-layer conductor pattern 62 (FIG. 1). The input terminal RFin is connected to the substrate side pad 102 with the second wire 92 interposed therebetween.

The second wire 92 connected to the ground terminal GND is disposed between the first-layer conductor pattern 61 that connects the input terminal RFin and the input terminal SWin to each other and the inter-member connection wire 73 that connects the output terminal SWout and the amplifier input terminal PAin to each other. Therefore, the decrease in the isolation between the high-frequency signal transmitted from the input terminal RFin to the input terminal SWin and the high-frequency signal transmitted from the output terminal SWout to the amplifier input terminal PAin is suppressed.

Further, four inter-member connection wires 73 are disposed so as to intersect the edge of the second member 40 in a plan view. The four inter-member connection wires 73 connect the output terminal SWout and the amplifier input terminal PAin to each other, connect the bias control terminal cont1 of the first member 20 and the bias control terminal cont1 of the second member 40 to each other, connect the bias control terminal cont2 of the first member 20 and the bias control terminal cont2 of the second member 40 to each other, and connect the power supply terminal Vbat2 and the power supply terminal Vbat3 to each other, respectively.

The amplifier output terminal PAout of the first member 20 is disposed in the vicinity of the region where the plurality of transistor cells constituting the output stage transistor T2 are arranged. In FIG. 5, the region where the plurality of transistor cells constituting the output stage transistor T2 are disposed is surrounded by a broken line. The temperature sensor 43d is disposed at a position that overlaps the region of the first member 20 where the output stage transistor T2 is disposed, in a plan view.

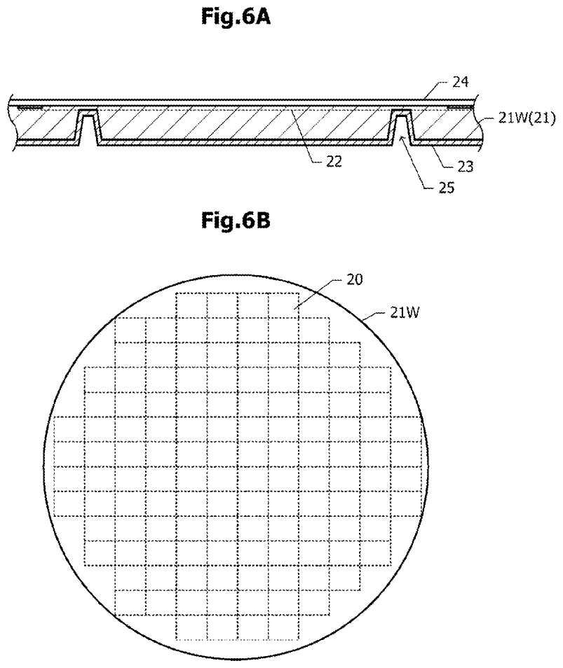

Next, a method of manufacturing the semiconductor device 100 according to the first embodiment will be described with reference to FIGS. 6A to 10E. FIGS. 6A, 7A, 8A, 9A, and 10A to 10E are cross-sectional views of the semiconductor device 100 at an intermediate stage of the manufacturing. FIGS. 6B, 7B, 8B, and 9B are plan views of the semiconductor device 100 at the intermediate stage of the manufacturing.

As illustrated in FIGS. 6A and 6B, a plurality of regions where the first member 20 is formed are defined in a compound semiconductor wafer 21W (semiconductor substrate 21 before division). The first electronic circuit 22 is formed in each of the regions where the first member 20 is formed. The insulating film 24 such as silicon nitride is deposited so as to cover the first electronic circuit 22. Further, a back side via 25 is formed from the back surface (the surface opposite to the surface covered with the insulating film 24) of the semiconductor substrate 21. The back side via 25 reaches to the conductor pattern included in the first electronic circuit 22. After that, the back surface conductor film 23 is deposited so as to cover the back surface of the semiconductor substrate 21 and the side surfaces and bottom surface of the back side via 25.

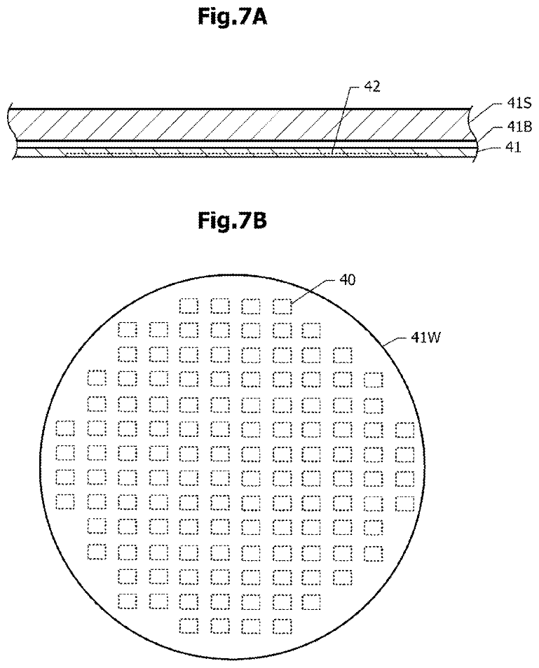

As illustrated in FIGS. 7A and 7B, an SOI wafer 41W including a support substrate 41S, an insulating layer 41B, and a semiconductor layer 41 is prepared. A plurality of regions where the second member 40 is formed are defined in the SOI wafer 41W. The second electronic circuit 42 is formed in the semiconductor layer 41 of each of the regions where the second members 40 are formed.

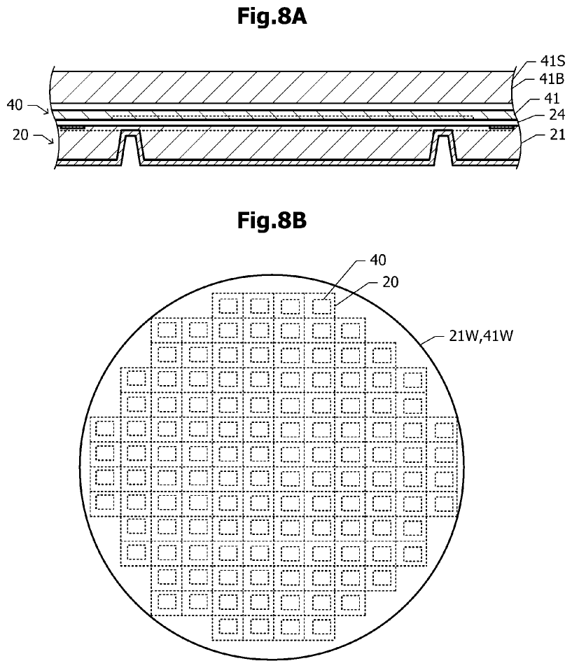

As illustrated in FIGS. 8A and 8B, the second member 40 in a wafer state is bonded to the first member 20 in a wafer state with the insulating film 24 of the first member 20 and the semiconductor layer 41 of the second member 40 facing each other. Here, the “bonding” means to bring the first member 20 and the second member 40 into surface contact and to bond the both without using an adhesive, or to bond the first member 20 and the second member 40 using an adhesive. For example, the bonding without an adhesive is by van der Waals bonding or hydrogen bonding. In addition, the bonding may be performed by electrostatic force, covalent bonding, or the like. In this case, in a plan view, positioning is realized so that the plurality of second members 40 provided on the SOI wafer 41W are included in each of the plurality of first members 20 provided on the compound semiconductor wafer 21W.

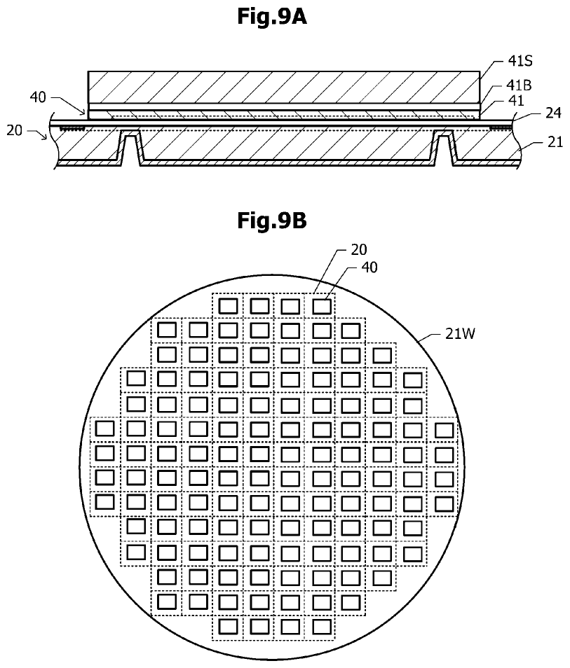

As illustrated in FIGS. 9A and 9B, by etching and removing a portion of the SOI wafer 41W (FIGS. 8A and 8B), the support substrate 41S, the insulating layer 41B, and the semiconductor layer 41 are isolated for each second member 40 of the semiconductor device 100 (FIG. 1).

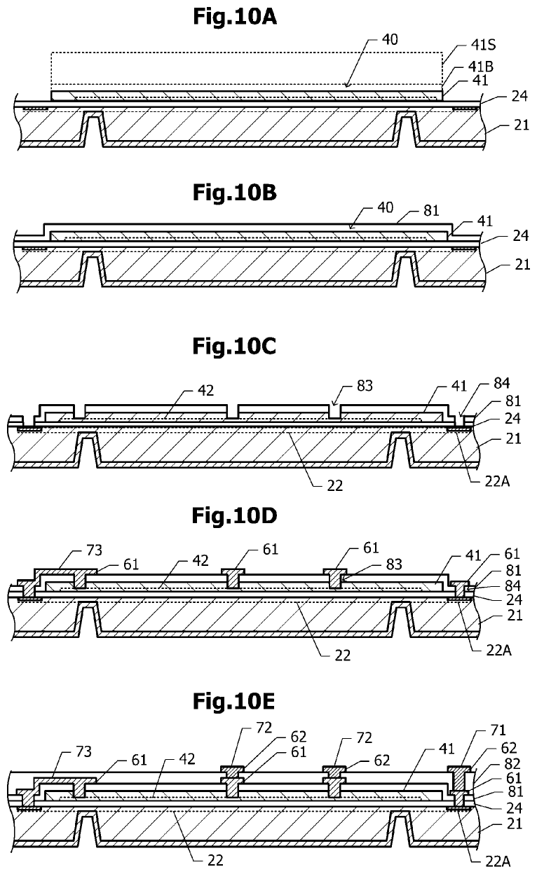

As illustrated in FIG. 10A, the support substrate 41S and the insulating layer 41B after being isolated for each second member 40 are removed by etching. In FIG. 10A, the support substrate 41S and the insulating layer 41B which are removed by etching are indicated by a broken line.

As illustrated in FIG. 10B, a first common insulating film 81 such as polyimide is deposited on the entire surface of the wafer so as to cover the semiconductor layer 41.

As illustrated in FIG. 10C, a plurality of contact holes 83 are formed at predetermined positions in the two layers of the first common insulating film 81 and the semiconductor layer 41, and a plurality of contact holes 84 are formed at predetermined positions in the two layers of the first common insulating film 81 and the insulating film 24. The contact hole 83 formed in the semiconductor layer 41 reaches the conductor pattern included in the second electronic circuit 42. The contact hole 84 formed in the insulating film 24 reaches the conductor pattern 22A of the first electronic circuit 22.

After the contact holes 83 and 84 are formed, the side surfaces and the bottom surface of the contact holes 83 and 84 and the surface of the first common insulating film 81 are coated with an insulating film. After that, the insulating film on the bottom surfaces of the contact holes 83 and 84 is removed. In this case, the insulating film is left on the side surfaces of the contact holes 83 and 84. To remove the insulating film on the bottom surfaces of the contact holes 83 and 84, the insulating film may be patterned by using normal photolithography technology. The insulating film may be removed by using anisotropic reactive ion etching.

As illustrated in FIG. 10D, the plurality of first-layer conductor patterns 61 are formed on the first common insulating film 81. The first-layer conductor pattern 61 is connected to at least one of the conductor pattern 22A of the first electronic circuit 22 and the conductor pattern (not illustrated) of the second electronic circuit 42. The first-layer conductor pattern 61 connected to both the first electronic circuit 22 and the second electronic circuit 42 configures the inter-member connection wire 73.

As illustrated in FIG. 10E, the second common insulating film 82 such as polyimide is deposited on the first common insulating film 81 so as to cover the first-layer conductor pattern 61, and a plurality of contact holes are formed at predetermined portions. After that, the plurality of second-layer conductor patterns 62 are formed on the second common insulating film 82. Some of the conductor patterns 62 are connected to the conductor pattern 22A of the first electronic circuit 22 with the first-layer conductor pattern 61 interposed therebetween and used as the first pad 71. Some other conductor patterns of the second-layer conductor patterns 62 are connected to the second electronic circuit 42 with the first-layer conductor pattern 61 interposed therebetween and used as the second pad 72.

After the second-layer conductor patterns 62 is formed, the wafer is isolated into the plurality of semiconductor devices 100 by cutting with a dicing machine. After that, the semiconductor device 100 is face-up mounted on the module substrate 101 (FIG. 2) and wire bonding is performed. In the wire bonding process, a wire is first bonded to the substrate side pad 102 and thereafter bonded to the first pad 71 and the second pad 72 of the semiconductor device 100.

Next, excellent effects of the first embodiment will be described.

In the first embodiment, the second member 40 bonded to the first member 20 is a thin film including the semiconductor layer 41. Therefore, it is possible to reduce the height of the semiconductor device as compared with a structure in which a die including a substrate made of a single semiconductor is stacked on a die including a substrate made of a compound semiconductor.

In addition, in the first embodiment, the inter-member connection wire 73 (FIG. 1) made of a conductor film is used to connect the first electronic circuit 22 of the first member 20 and the second electronic circuit of the second member 40. Therefore, an excellent effect that the parasitic resistance and the parasitic inductance of the wiring are reduced is obtained as compared with a configuration in which the both are connected by a bonding wire.

For example, since the parasitic inductance of the wiring that connects the inter-stage impedance matching circuit 31 (FIG. 3) and the MOS transistors S4 and S5 is reduced, the design of the inter-stage impedance matching circuit 31 is easy. Further, since the parasitic inductance of the wiring that connects the harmonic wave termination circuit 32 (FIG. 3) and the MOS transistors S2 and S3 to each other is reduced, the design of the harmonic wave termination circuit 32 is easy. Further, since the parasitic inductance of the wiring that connects the diode D1 and the MOS transistor Si in parallel in the protection circuit 33 (FIG. 3) is reduced, the operation delay due to the inductance component can be suppressed.

Further, by using the inter-member connection wire 73 (FIG. 1), the number of bonding wires can be reduced. Accordingly, the time required for the wire bonding process can be reduced.

Further, in the first embodiment, since the second member 40 is a thin film, the step generated at the edge of the second member 40 is reduced as compared with a case where a silicon die or the like is used as the second member 40. Therefore, a good effect is obtained that disconnection of the inter-member connection wire 73 (FIG. 1) that intersects the edge of the second member 40 in a plan view is less likely to occur.

Further, in the first embodiment, the first wire 91 (FIG. 2) is first bonded to the substrate side pad 102 and thereafter bonded to the first pad 71. Therefore, the end portion of the first wire 91 connected to the first pad 71 is inclined to be larger than the end portion connected to the substrate side pad 102 in a normal direction of a mounting surface of the module substrate 101. The same applies to the second wire 92. Therefore, the dimension in the thickness direction of the semiconductor module including the first wire 91 and the second wire 92 can be reduced.

Next, a modification example of the first embodiment will be described.

In the first embodiment, the conductor pattern 22A provided on the first member 20 is covered with the insulating film 24, but there may be a configuration in which the conductor pattern 22A is exposed on the upper surface 20A of the first member 20. Further, in the first embodiment, the first electronic circuit 22 provided on the first member 20 includes the high-frequency amplifier circuit, and the second electronic circuit 42 provided on the second member 40 includes a control circuit of the high-frequency amplifier circuit.

However, electronic circuits having other functions may be employed as the first electronic circuit 22 and the second electronic circuit 42. For example, when a compound semiconductor element is suitable for realizing the function of the first electronic circuit 22 and a single semiconductor element is suitable for realizing the function of the second electronic circuit 42, it is preferable to employ the configuration of the semiconductor device 100 according to the first embodiment.

In the first embodiment, after the SOI wafer 41W is isolated for each second member 40 in the processes illustrated in FIGS. 9A and 9B, the support substrate 41S and the insulating layer 41B are removed by etching in the process illustrated in FIG. 10A. The order may be reversed, first, the support substrate 41S and the insulating layer 41B may be removed by etching, and thereafter the semiconductor layer 41 may be isolated for each second member 40.

### Second Embodiment

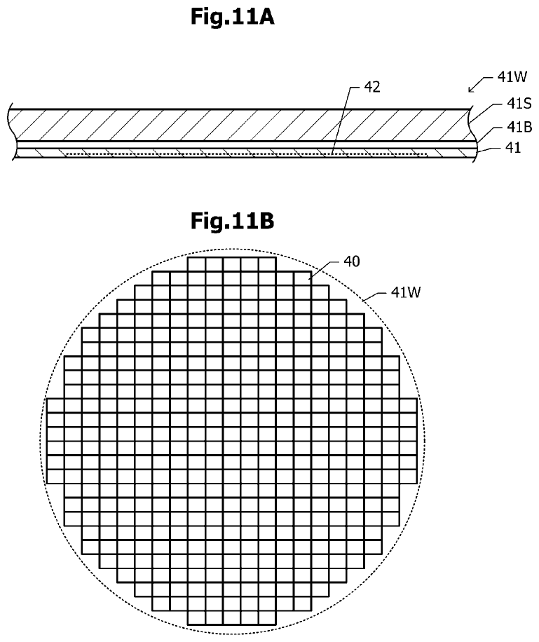

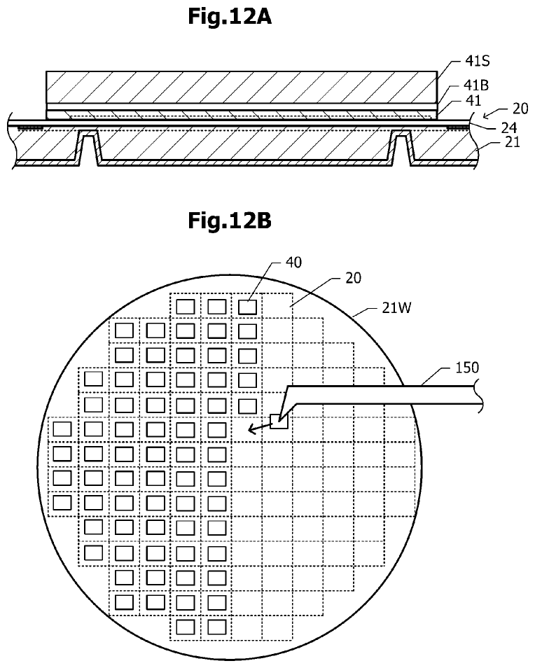

Next, a semiconductor device according to a second embodiment will be described with reference to FIGS. 11A to 12B. A structure of a semiconductor device 100 according to the second embodiment is the same as the structure of the semiconductor device 100 (FIG. 1) according to the first embodiment. In the second embodiment, a method of manufacturing the semiconductor device 100 is different from the method of manufacturing the semiconductor device 100 according to the first embodiment described with reference to FIGS. 6A to 10E.

FIGS. 11A and 12A are cross-sectional views of the semiconductor device 100 in an intermediate stage of manufacturing. FIGS. 11B and 12B are plan views of the semiconductor device 100 at the intermediate stage of the manufacturing.

The manufacturing process related to the compound semiconductor wafer 21W for manufacturing the first member 20 is the same as the wafer process in the manufacturing method of the semiconductor device 100 according to the first embodiment illustrated in FIGS. 6A and 6B.

As illustrated in FIGS. 11A and 11B, the second electronic circuit 42 is formed in each of a plurality of regions where the second member 40 is formed in the semiconductor layer 41 of the SOI wafer 41W. In the first embodiment, as illustrated in FIG. 7B, the region where the second member 40 is formed corresponds to the region where the first member 20 is formed in the compound semiconductor wafer 21W illustrated in FIG. 6B in a one-to-one manner. Therefore, the region where the second member 40 is formed which is smaller than the first member 20 is disposed at an interval in the surface of the SOI wafer 41W.

Meanwhile, in the second embodiment, as illustrated in FIG. 11B, the region where the second member 40 is to be formed is disposed in close contact with the surface of the SOI wafer 41W. The cross-sectional structure of the SOI wafer 41W illustrated in FIG. 11A is the same as the cross-sectional structure illustrated in FIG. 7A at the intermediate stage of manufacturing the semiconductor device 100 according to the first embodiment.

In the second embodiment, before the SOI wafer 41W is bonded to the compound semiconductor wafer 21W, the SOI wafer 41W is cut with a dicing machine, and thus, divided into each second member 40. In FIG. 11B, the fact that an outer peripheral line of the second member 40 is indicated by a solid line and an outer peripheral line of the SOI wafer 41W is indicated by a dashed line indicates that the SOI wafer 41W is divided into the plurality of second members 40.

As illustrated in FIGS. 12A and 12B, the plurality of second members 40 before the support substrate 41S and the insulating layer 41B are removed are bonded to the first member 20 in a wafer state. A chip mounter 150 is used to position the second member 40 with respect to the first member 20. A state in which the plurality of divided second members 40 are bonded to the first member 20 in a wafer state is the same as the structure illustrated in FIGS. 9A and 9B at the intermediate stage of manufacturing the semiconductor device 100 according to the first embodiment.

The processes after bonding the plurality of second members 40 to the first member 20 are the same as the processes described with reference to FIGS. 10A to 10E of the method of manufacturing according to the first embodiment.

Next, excellent effects of the second embodiment will be described.

In the first embodiment, as illustrated in FIGS. 8A and 8B, the second member 40 in a wafer state is bonded to the first member 20 in a wafer state. Therefore, it is necessary to use wafers having the same dimension as the compound semiconductor wafer 21W on which the first member 20 is formed and the SOI wafer 41W on which the second member 40 is formed. Meanwhile, in the second embodiment, as illustrated in FIGS. 12A and 12B, the divided second member 40 is bonded to the first member 20 in a wafer state. Therefore, as the SOI wafer 41W, a wafer having different dimensions from the compound semiconductor wafer 21W can be used.

Further, in the first embodiment, as illustrated in FIG. 7B, the plurality of second members 40 are disposed at distances from each other on the surface of the SOI wafer 41W. Meanwhile, in the second embodiment, as illustrated in FIG. 11B, the plurality of second members 40 are disposed in close contact with the surface of the SOI wafer 41W. Therefore, the utilization efficiency of the SOI wafer 41W can be improved.

### Third Embodiment

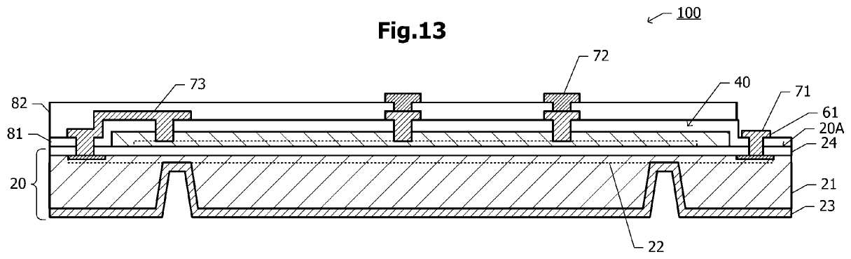

Next, a semiconductor device according to a third embodiment will be described with reference to FIG. 13.

Hereinafter, the description of the configuration in common with the semiconductor device 100 according to a first embodiment described with reference to FIGS. 1 to 10E will be omitted.

FIG. 13 is a cross-sectional view of a semiconductor device 100 according to the third embodiment. In the first embodiment (FIG. 1), some of the plurality of second-layer conductor patterns 62 disposed on the second common insulating film 82 are used as the first pads 71. Meanwhile, in the third embodiment, some of the plurality of first-layer conductor patterns 61 disposed on the first common insulating film 81 are used as the first pads 71. The second common insulating film 82 in the region where the first pad 71 is disposed is removed, and the first pad 71 is exposed. As described above, in the third embodiment, the first pad 71 is disposed at a position lower than the second pad 72 with the lower surface of the first member 20 or the mounting surface of the module substrate 101 (FIG. 2) as a height reference.

Next, excellent effects of the third embodiment will be described. As in the first embodiment (FIG. 1), in the configuration in which the second-layer conductor pattern 62 is used as the first pad 71, the first-layer conductor pattern 61 is interposed between the first pad 71 and the conductor pattern 22A of the first electronic circuit 22. Meanwhile, in the third embodiment, since the first-layer conductor pattern 61 is used as the first pad 71, the first pad 71 is directly connected to the conductor pattern 22A of the first electronic circuit 22. Therefore, the increase in the resistance component of the wiring that connects the first electronic circuit 22 and the substrate side pad 102 (FIG. 2) is suppressed.

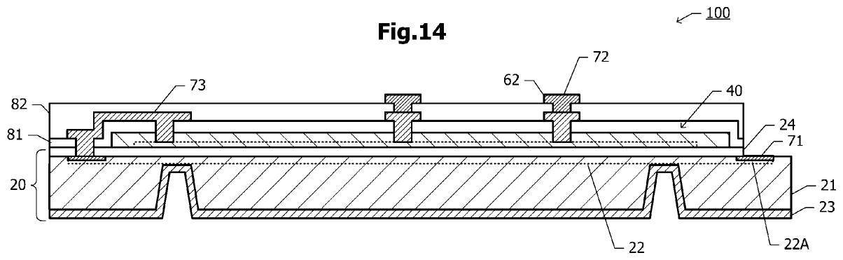

Next, a semiconductor device according to a modification example of the third embodiment will be described with reference to FIG. 14.

FIG. 14 is a cross-sectional view of the semiconductor device according to the modification example of a third embodiment. In the third embodiment (FIG. 13), at least one of the plurality of first-layer conductor patterns 61 is used as the first pad 71. Meanwhile, in the modification example illustrated in FIG. 14, at least one of the conductor patterns 22A included in the first electronic circuit 22 is used as the first pad 71.

In a plan view, the insulating film 24 in a region overlapping the conductor pattern 22A used as the first pad 71, the first common insulating film 81, and the second common insulating film 82 are removed, and the conductor pattern 22A is exposed. For example, Au is used for the conductor pattern 22A. For example, Cu is used for the second-layer conductor pattern 62 used as the second pad 72. As described above, different metals from each other are used as the first pad 71 and the second pad 72.

Next, excellent effects of the modification example of the third embodiment will be described. In the present modification example, the conductor pattern 22A included in the first electronic circuit 22 is used as the first pad 71 for bonding. Therefore, the increase in the resistance component of the wiring that connects the first electronic circuit 22 and the substrate side pad 102 (FIG. 2) to each other is further suppressed.

### Fourth Embodiment

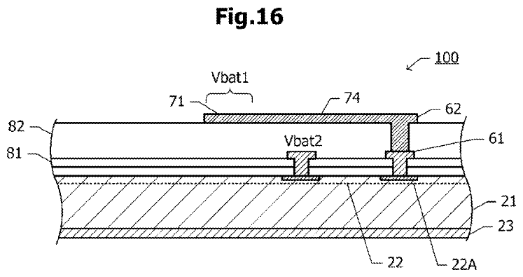

Next, a semiconductor device and a semiconductor module according to a fourth embodiment will be described with reference to FIGS. 15 and 16. Hereinafter, the description of the configuration in common with the semiconductor device 100 according to a first embodiment described with reference to FIGS. 1 to 10E will be omitted.

FIG. 15 is a diagram illustrating a positional relationship of the terminals provided on the first member 20 and the second member 40 of the semiconductor device 100 and the substrate side pad provided on the module substrate 101 (FIG. 2) according to the fourth embodiment in a plan view.

When the first embodiment (FIG. 5) and the fourth embodiment are compared, the connection configuration between the power supply terminal Vbat1 and the conductor pattern 22A of the first electronic circuit 22 is different. In the first embodiment (FIG. 5), the first pad 71 used as the power supply terminal Vbat1 is disposed immediately above the conductor pattern 22A connected to the power supply terminal Vbat1. Meanwhile, in the fourth embodiment, the power supply terminal Vbat1 and the conductor pattern 22A connected thereto are disposed at different positions. The power supply terminal Vbat1 is connected to the conductor pattern 22A with a cross wire 74 interposed therebetween. In FIG. 15, the cross wire 74 is attached with the same hatching as the second pad 72.

In a plan view, the power supply terminal Vbat2 is disposed between the power supply terminal Vbat1 and the conductor pattern 22A connected thereto. The cross wire 74 partially overlaps the power supply terminal Vbat2 in a plan view. The cross wire 74 is connected to the first pad 71 on one side when viewed from the portion overlapping the power supply terminal Vbat2 and is connected to the conductor pattern 22A of the first electronic circuit 22 on the other side.

FIG. 16 is a cross-sectional view of the semiconductor device 100 in a region where the cross wire 74 and the power supply terminal Vbat2 overlap each other in a plan view. The power supply terminal Vbat1 and the cross wire 74 are configured with the second- layer conductor pattern 62. The end portion of the cross wire 74 opposite to the end portion on the power supply terminal Vbat1 side is connected to the conductor pattern 22A of the first electronic circuit 22 with the first-layer conductor pattern 61 interposed therebetween. The cross wire 74 passes above the power supply terminal Vbat2 configured with the first-layer conductor pattern 61. The cross wire 74 and the power supply terminal Vbat2 are insulated from each other by the second common insulating film 82.

Next, excellent effects of the fourth embodiment will be described.

In the fourth embodiment, the conductor pattern 22A of the first electronic circuit 22 and the first pad 71 connected thereto are connected to each other with the cross wire 74 interposed therebetween. Therefore, the first pad 71 does not need to be disposed immediately above the conductor pattern 22A connected thereto, and an excellent effect is obtained that the degree of freedom in the disposition of the first pad 71 increases.

### Fifth Embodiment

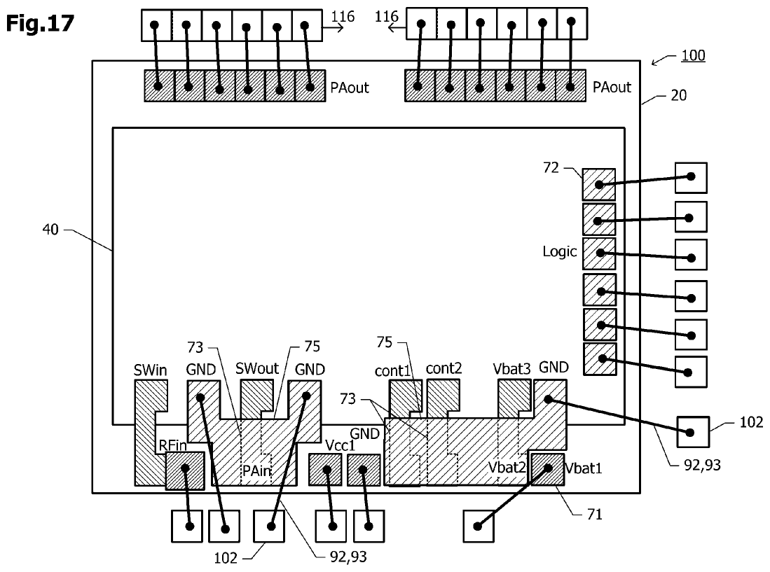

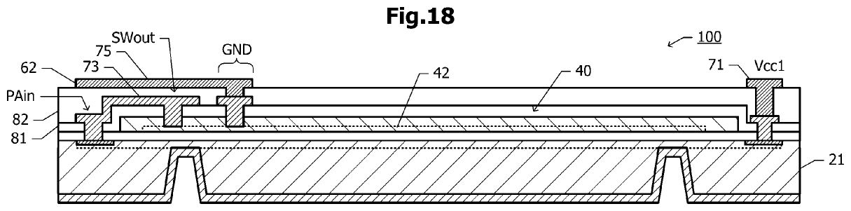

Next, a semiconductor device and a semiconductor module according to a fifth embodiment will be described with reference to FIGS. 17 and 18. Hereinafter, the description of the configuration in common with the semiconductor device 100 according to a first embodiment described with reference to FIGS. 1 to 10E will be omitted.

FIG. 17 is a diagram illustrating a positional relationship between the terminals provided on the first member 20 and the second member 40 of the semiconductor device 100 and the substrate side pad provided on the module substrate 101 (FIG. 2) according to the fifth embodiment in a plan view.

In the fifth embodiment, at least one shield film 75 is disposed so as to overlap the inter-member connection wire 73 through which the high-frequency signal or the control signal is transmitted. In FIG. 17, the shield film 75 is indicated by the same hatching as the second pad 72. For example, one shield film 75 overlaps the inter-member connection wire 73 that connects the output terminal SWout and the amplifier input terminal PAin, and the other shield film 75 overlaps the two inter-member connection wire 73 connected to the bias control terminals cont1 and cont2. The shield film 75 is connected to the ground terminal GND of the second member 40. The ground terminal GND is connected to the ground substrate side pad 102 of the module substrate 101 (FIG. 2) by the second wire 92.

As described above, the shield film 75 is connected to the ground of the module substrate 101 (FIG. 2) with the ground terminal GND and the second wire 92 interposed therebetween. The second wire 92 connected to the shield film 75 may be referred to as a third wire 93. In the embodiment illustrated in FIG. 17, the second wire 92 that connects the ground terminal GND and the substrate side pad 102 to each other also serves as the third wire 93 that connects the shield film 75 to the ground substrate side pad 102.

FIG. 18 is a cross-sectional view of the semiconductor device 100 focusing on the region where the shield film 75 is disposed. The inter-member connection wire 73 connects the output terminal SWout on the second member 40 to the amplifier input terminal PAin on the first member 20. The shield film 75 is disposed above the inter-member connection wire 73 with the second common insulating film 82 interposed therebetween. The shield film 75 is configured with the second-layer conductor pattern 62, and is in succession with the ground terminal GND configured with the second-layer conductor pattern 62.

Next, excellent effects of the fifth embodiment will be described.

In the fifth embodiment, since the shield film 75 is disposed so as to overlap the inter-member connection wire 73 through which the high-frequency signal is transmitted, the isolation between the high-frequency signal and other circuits can be improved. For example, in the embodiment illustrated in FIG. 17, the amplifier input terminal PAin and the collector power supply terminal Vcc1 are disposed to be adjacent to each other. Since the shield film 75 is disposed so as to overlap the inter-member connection wire 73 connected to the amplifier input terminal PAin, the isolation between the high-frequency signal and the collector power supply can be improved. Accordingly, the high-frequency signal component returning to the amplifier input terminal PAin through the collector power supply can be suppressed, and the stability of the operation of the high frequency power amplifier circuit can be improved.

Further, since the shield film 75 is disposed so as to overlap the inter-member connection wire 73 through which the control signal is transmitted, the isolation between the control signal and other circuits can be improved. For example, in the embodiment illustrated in FIG. 17, the interference between the control signal transmitted through the inter-member connection wire 73 connected to the bias control terminals cont1 and cont2 and the collector power supply is suppressed, and the generation of noise or unnecessary spurious is reduced.

Next, a modification example of the fifth embodiment will be described. In the fifth embodiment, the shield film 75 is coupled to the ground terminal GND configured with the second pad 72.

Therefore, the second wire 92 that connects the ground terminal GND to the ground substrate side pad 102 is shared with the third wire 93 that connects the shield film 75 to the ground substrate side pad 102. As another configuration, the third wire 93 that connects the shield film 75 to the ground substrate side pad 102 may be provided separately from the second wire 92. In this case, the shield film 75 does not need to be connected to the ground terminal GND.

### Sixth Embodiment

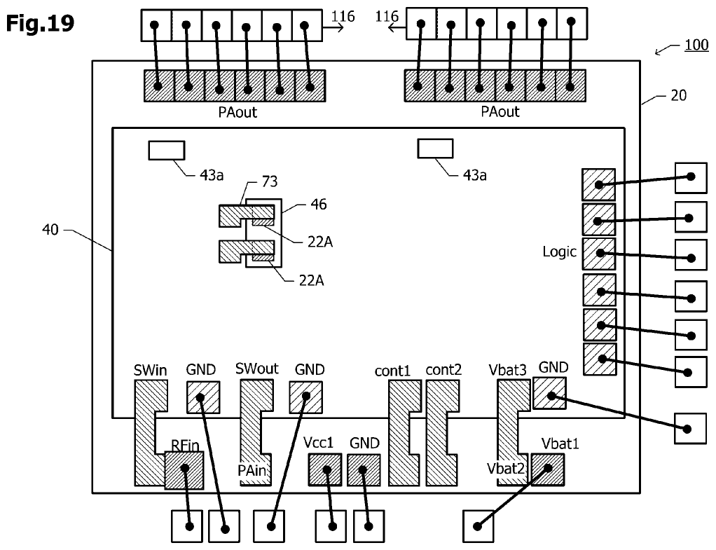

Next, a semiconductor device and a semiconductor module according to a sixth embodiment will be described with reference to FIG. 19. Hereinafter, the description of the configuration in common with the semiconductor device 100 according to a first embodiment described with reference to FIGS. 1 to 10E will be omitted.

FIG. 19 is a diagram illustrating a positional relationship between the terminals provided on the first member 20 and the second member 40 and the substrate side pad provided on the module substrate 101 (FIG. 2) of the semiconductor device 100 according to a sixth embodiment in a plan view.

In the first embodiment (FIG. 5), all the inter-member connection wires 73 are disposed so as to intersect the outer peripheral edge of the second member 40 in a plan view. Meanwhile, in the sixth embodiment, an opening 46 is provided in the second member 40 in a plan view. The conductor pattern 22A of the first electronic circuit 22 is exposed on the bottom surface of the opening 46. Some inter-member connection wires 73 of the plurality of inter-member connection wires 73 are disposed so as to intersect the edge of the opening 46.

One end portion of the inter-member connection wire 73 is connected to the conductor pattern 22A in the opening 46, and the other end portion is connected to the second electronic circuit 42 (FIG. 1) through a contact hole provided in the first common insulating film 81 and the semiconductor layer 41 (FIG. 1). For example, the inter-member connection wire 73 intersecting the edge of the opening 46 is provided for the connection between the MOS transistors 51, S2, S3, S4 and S5 of the second electronic circuit 42 illustrated in FIG. 3 and the controlled circuit included in the first electronic circuit 22.

In FIG. 19, only one opening 46 and the two inter-member connection wires 73 that intersect the edge thereof are illustrated, but the edge of the one opening 46 and three or more inter-member connection wires 73 may intersect each other, and a plurality of openings 46 may be provided.

Next, excellent effects of the sixth embodiment will be described.

In the sixth embodiment, the inter-member connection wire 73 can be disposed inside the outer peripheral line of the second member 40 in a plan view. Therefore, a degree of freedom in the disposition of the inter-member connection wire 73 can be increased. The position and number of the openings 46 may be determined according to the disposition of the MOS transistors S1, S2, S3, S4, and S5 connected by the inter-member connection wire 73 and the controlled circuit.

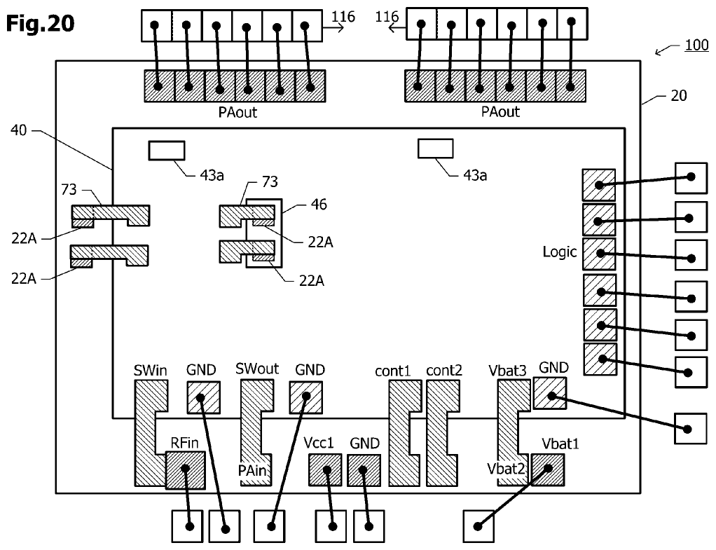

Next, a semiconductor device according to a modification example of the sixth embodiment will be described with reference to FIG. 20. In the present modification example, for example, the inter-member connection wire 73 intersecting the edge of the second member 40 is used for a portion of the connection between the MOS transistors S1, S2, S3, S4, and S5 of the second electronic circuit 42 illustrated in FIG. 3 and the controlled circuit included in the first electronic circuit 22. As described above, in the plurality of inter-member connection wires 73 for connecting the MOS transistors S1, S2, S3, S4, and S5 of the second electronic circuit 42 illustrated in FIG. 3 to the controlled circuit included in the first electronic circuit 22, the inter-member connection wire that intersects the edge of the opening 46 and the inter-member connection wire that intersects the edge of the second member 40 may be mixed. The inter-member connection wire that intersects the edge of the second member 40 may be used as all of the inter-member connection wires 73.

### Seventh Embodiment

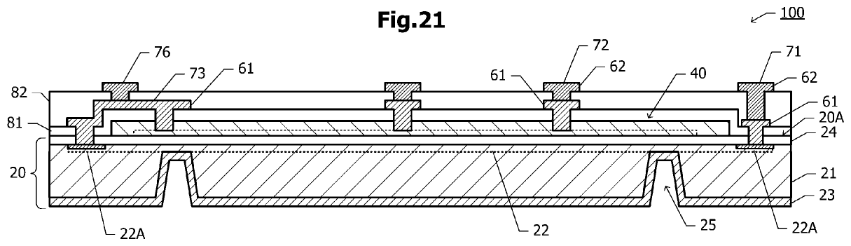

Next, a semiconductor device according to a seventh embodiment will be described with reference to FIG. 21.

Hereinafter, the description of the configuration in common with the semiconductor device 100 according to a first embodiment described with reference to FIGS. 1 to 10E will be omitted.

FIG. 21 is a cross-sectional view of a semiconductor device 100 according to the seventh embodiment. In the first embodiment (FIG. 1), the inter-member connection wire 73 is not connected to the wire bonding pad. Meanwhile, in the seventh embodiment, the inter-member connection wire 73 is connected to a third pad 76 for wire bonding disposed on the second common insulating film 82.

Next, excellent effects of the seventh embodiment will be described.

In the seventh embodiment, the inter-member connection wire 73 can be connected to substrate side pad 102 of the module substrate 101 (FIG. 2) with a bonding wire interposed therebetween. For example, the inter-member connection wire 73 on the ground side that connects the MOS transistor S1 and the diode D1 illustrated in FIG. 3 can be connected to the ground of the first electronic circuit 22 and connected to the ground substrate side pad 102 of the module substrate 101 (FIG. 2).

### Eighth Embodiment

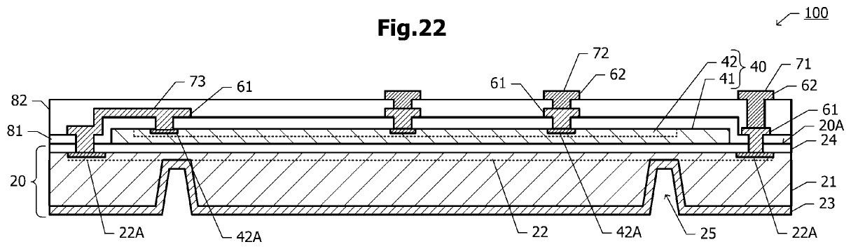

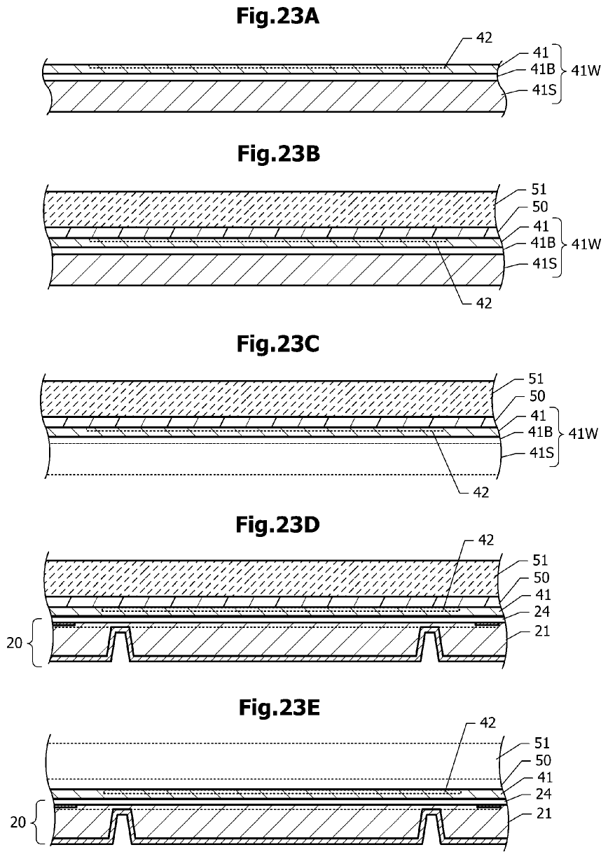

Next, a semiconductor device according to an eighth embodiment will be described with reference to FIGS. 22 to 23E. Hereinafter, the description of the configuration in common with the semiconductor device 100 according to a first embodiment described with reference to FIGS. 1 to 10E will be omitted.

FIG. 22 is a cross-sectional view of a semiconductor device 100 according to the eighth embodiment. In the first embodiment (FIG. 1), the second electronic circuit 42 is provided on the surface of the semiconductor layer 41 facing the first member 20. Meanwhile, in the eighth embodiment, the second electronic circuit 42 is provided on the surface (upper surface) of the semiconductor layer 41 opposite to the surface facing the first member 20. The second electronic circuit 42 includes a plurality of conductor patterns 42A. The plurality of conductor patterns 42A are exposed on the upper surface of the second member 40.

In the first embodiment (FIG. 1), the first-layer conductor pattern 61 is connected to the conductor pattern of the second electronic circuit 42 disposed in the vicinity of the lower surface of the semiconductor layer 41 through the contact hole provided in the semiconductor layer 41. Meanwhile, in the eighth embodiment, the first-layer conductor pattern 61 is connected to the conductor pattern 42A of the second electronic circuit 42 disposed on the upper surface of the semiconductor layer 41.

Next, a method of manufacturing the semiconductor device 100 according to the eighth embodiment will be described with reference to FIGS. 23A to 23E. The drawings from FIGS. 23A to 23E are cross-sectional views at an intermediate stage of manufacturing the semiconductor device 100 according to an eighth embodiment.

As illustrated in FIG. 23A, the second electronic circuit 42 is formed in the semiconductor layer 41 of the SOI wafer 41W including the support substrate 41S, the insulating layer 41B, and the semiconductor layer 41. This process is the same as the process described with reference to FIGS. 7A and 7B in the first embodiment.

As illustrated in FIG. 23B, the semiconductor layer 41 faces a temporary substrate 51, and the temporary substrate 51 is bonded to the SOI wafer 41W by an adhesive layer 50. As the temporary substrate 51, for example, a glass substrate is used.

As illustrated in FIG. 23C, the support substrate 41S and the insulating layer 41B are removed by etching. In FIG. 23C, the support substrate 41S and the insulating layer 41B which are removed by etching are indicated by a broken line. As a result, the surface (hereinafter, referred to as a bonding surface) of the semiconductor layer 41 opposite to the surface on which the second electronic circuit 42 is formed is exposed.

As illustrated in FIG. 23D, the semiconductor layer 41 is bonded to the first member 20 with the bonding surface of the semiconductor layer 41 facing the first member 20 in a wafer state.

As illustrated in FIG. 23E, the temporary substrate 51 and the adhesive layer 50 are removed from the first member 20 in a wafer state. After that, the semiconductor layer 41 is isolated for each second member 40. Through the steps so far, a structure substantially the same as the structure illustrated in FIG. 10A at an intermediate stage of manufacturing the semiconductor device 100 according to the first embodiment is obtained. However, in the eighth embodiment, the second electronic circuit 42 is formed on the surface of the semiconductor layer 41 opposite to the surface that faces the first member 20.

After that, similarly to the process described with reference to the drawings from FIGS. 10C to 10E of the first embodiment, the first common insulating film 81, the first-layer conductor pattern 61, the second common insulating film 82, and the second-layer conductor pattern 62 are formed.

Next, excellent effects of the eighth embodiment will be described.

Similarly to the first embodiment, in the eighth embodiment, the height of the semiconductor device 100 can be reduced. Further, in the first embodiment, in the process described with reference to FIG. 10C, the contact hole 83 that substantially penetrates both the first common insulating film 81 and the semiconductor layer 41 to expose the conductor pattern of the second electronic circuit 42 is formed. Meanwhile, in the eighth embodiment, it is not necessary to form the contact hole in the semiconductor layer 41.

The following disclosure is disclosed based on the above-described embodiments described in the present specification.
<1> There is provided a semiconductor module including a module substrate that has a plurality of substrate side pads disposed on a surface; a first member that is mounted on a mounting surface of the module substrate, and includes a semiconductor substrate made of a compound semiconductor and a first electronic circuit provided on the semiconductor substrate; and a second member that is bonded to an upper surface of the first member, and includes a semiconductor layer made of a single semiconductor thinner than the semiconductor substrate and a second electronic circuit provided on the semiconductor layer. The semiconductor module also includes a first pad that is disposed on the first member and is connected to the first electronic circuit; a second pad that is disposed on the second member and is connected to the second electronic circuit; a first wire that connects the first pad and one of the plurality of substrate side pads to each other; a second wire that connects the second pad and one of the plurality of substrate side pads to each other; and an inter-member connection wire made of a conductor film that is disposed on the first member and the second member and connects the first electronic circuit and the second electronic circuit to each other.
<2> The semiconductor module according to <1>, wherein in a plan view, the second member is smaller than the first member, and the first pad is disposed at a position that does not overlap the second member, and the first pad is disposed at a position lower than the second pad with the mounting surface of the module substrate as a height reference.
<3> The semiconductor module according to <1> or <2>, wherein the second electronic circuit is formed on a surface of the semiconductor layer that faces the first member, and the semiconductor module further includes a via conductor that extends in a thickness direction from a surface opposite to the surface on which the second electronic circuit is formed and connects the second pad and the second electronic circuit to each other.
<4> The semiconductor module according to any one of <1> to <3>, further includes a first common insulating film that continuously covers a region from an upper surface of the second member to the upper surface of the first member, and a cross wire made of a conductor film connected to the first pad. The cross wire is connected to the first pad at one end portion and is connected to the first electronic circuit at a position different from the first pad in a plan view.
<5> The semiconductor module according to any one of <1> to <4>, wherein at least one of the plurality of substrate side pads is for a ground, and the semiconductor module further includes a second common insulating film that is disposed on the inter-member connection wire, a shield film made of a conductor film that is disposed on the second common insulating film and overlaps the inter-member connection wire in a plan view, and a third wire that connects the shield film and a ground pad among the plurality of substrate side pads to each other.
<6> The semiconductor module according to any one of <1> to <5>, wherein the second electronic circuit further includes a temperature dependent element whose characteristic changes according to a temperature, and a control circuit that controls an operation of the first electronic circuit in accordance with the change in the characteristic of the temperature dependent element.
<7> The semiconductor module according to any one of <1> to <6>, wherein an end portion of the first wire connected to the first pad is greatly inclined with respect to a normal direction of the mounting surface of the module substrate compared to an end portion connected to the substrate side pad.
<8> The semiconductor module according to any one of <1> to <7>, wherein the second electronic circuit includes at least one switching transistor, the first electronic circuit includes a controlled circuit whose operating state is switched by on and off of the switching transistor, and the inter-member connection wire connects the switching transistor and the controlled circuit to each other.
<9> The semiconductor module according to <8>, wherein the first electronic circuit includes an impedance matching circuit including a plurality of passive elements, and one of the switching transistors is connected to at least one of the plurality of passive elements.
<10> The semiconductor module according to <8> or <9>, wherein the first electronic circuit includes a protection circuit including a plurality of diodes connected in series, and one of the switching transistors is connected in parallel to some of the plurality of diodes constituting the protection circuit.
<11> A semiconductor device including a first member that includes a semiconductor substrate made of a compound semiconductor, and a first electronic circuit provided on an upper surface which is one surface of the semiconductor substrate; a second member that is bonded to the upper surface of the first member, and includes a semiconductor layer made of a single semiconductor thinner than the semiconductor substrate and a second electronic circuit provided on the semiconductor layer; a first pad that is disposed on the first member and is connected to the first electronic circuit; a second pad that is disposed on the second member and is connected to the second electronic circuit; and an inter-member connection wire made of a conductor film that is disposed on the first member and the second member and connects the first electronic circuit and the second electronic circuit to each other.

Each of the above-described embodiments is an example, and it goes without saying that partial replacement or combination of configurations illustrated in different embodiments is possible. The same operation and effect due to the same configuration of a plurality of embodiments will not be sequentially referred to for each embodiment. Furthermore, the present disclosure is not limited to the above-described embodiments. For example, it will be obvious to a person skilled in the art that various changes, improvements, combinations, and the like are possible.

What is claimed is:

1. A semiconductor module comprising:
a module substrate that has a plurality of substrate side pads on a surface;
a first member that is mounted on a mounting surface of the module substrate, and includes a semiconductor substrate including a compound semiconductor and a first electronic circuit on the semiconductor substrate;
a second member that is bonded to an upper surface of the first member, and includes a semiconductor layer configured of a single semiconductor thinner than the semiconductor substrate and a second electronic circuit on the semiconductor layer;
a first pad that is on the first member and is connected to the first electronic circuit;
a second pad that is on the second member and is connected to the second electronic circuit;
a first wire that connects the first pad and one of the plurality of substrate side pads to each other;
a second wire that connects the second pad and one of the plurality of substrate side pads to each other; and
an inter-member connection wire including a conductor film that is on the first member and the second member and connects the first electronic circuit and the second electronic circuit to each other.

2. The semiconductor module according to claim 1, wherein
in plan view, the second member is smaller than the first member, and the first pad is at a position that does not overlap the second member, and
the first pad is at a position lower than the second pad with the mounting surface of the module substrate as a height reference.

3. The semiconductor module according to claim 1, wherein
the second electronic circuit is on a surface of the semiconductor layer that faces the first member, and
the semiconductor module further includes a via conductor that extends in a thickness direction from a surface opposite to the surface on which the second electronic circuit is present and connects the second pad and the second electronic circuit to each other.

4. The semiconductor module according to claim 1, further comprising:
a first common insulating film that continuously covers a region from an upper surface of the second member to the upper surface of the first member; and
a cross wire configured of a conductor film connected to the first pad,
wherein the cross wire is connected to the first pad at one end portion and is connected to the first electronic circuit at a position different from the first pad in a plan view.

5. The semiconductor module according to claim 1, wherein
at least one of the plurality of substrate side pads is for a ground, and
the semiconductor module further includes
a second common insulating film that is on the inter-member connection wire,
a shield film configured of a conductor film that is on the second common insulating film and overlaps the inter-member connection wire in a plan view, and
a third wire that connects the shield film and a ground pad among the plurality of substrate side pads to each other.

6. The semiconductor module according to claim 1, wherein
the second electronic circuit further includes
a temperature dependent element whose characteristic changes according to a temperature, and
a control circuit configured to control an operation of the first electronic circuit in accordance with the change in the characteristic of the temperature dependent element.

7. The semiconductor module according to claim 1, wherein
an end portion of the first wire connected to the first pad is higher than an end portion connected to the substrate side pad with respect to a normal direction of the mounting surface of the module substrate.

8. The semiconductor module according to claim 1, wherein
the second electronic circuit includes at least one switching transistor,
the first electronic circuit includes a controlled circuit whose operating state is switched by on and off of the switching transistor, and
the inter-member connection wire connects the switching transistor and the controlled circuit to each other.

9. The semiconductor module according to claim 8, wherein
the first electronic circuit includes an impedance matching circuit including a plurality of passive elements, and
one of the switching transistors is connected to at least one of the plurality of passive elements.

10. The semiconductor module according to claim 8, wherein
the first electronic circuit includes a protection circuit including a plurality of diodes connected in series, and
one of the switching transistors is connected in parallel to some of the plurality of diodes configuring the protection circuit.

11. The semiconductor module according to claim 2, wherein
the second electronic circuit is on a surface of the semiconductor layer that faces the first member, and
the semiconductor module further includes a via conductor that extends in a thickness direction from a surface opposite to the surface on which the second electronic circuit is present and connects the second pad and the second electronic circuit to each other.

12. The semiconductor module according to claim 2, further comprising:
a first common insulating film that continuously covers a region from an upper surface of the second member to the upper surface of the first member; and
a cross wire configured of a conductor film connected to the first pad,
wherein the cross wire is connected to the first pad at one end portion and is connected to the first electronic circuit at a position different from the first pad in a plan view.

13. The semiconductor module according to claim 2, wherein
at least one of the plurality of substrate side pads is for a ground, and
the semiconductor module further includes
a second common insulating film that is on the inter-member connection wire,
a shield film configured of a conductor film that is on the second common insulating film and overlaps the inter-member connection wire in a plan view, and
a third wire that connects the shield film and a ground pad among the plurality of substrate side pads to each other.

14. The semiconductor module according to claim 2, wherein
the second electronic circuit further includes
a temperature dependent element whose characteristic changes according to a temperature, and
a control circuit configured to control an operation of the first electronic circuit in accordance with the change in the characteristic of the temperature dependent element.

15. The semiconductor module according to claim 2, wherein
an end portion of the first wire connected to the first pad is higher than an end portion connected to the substrate side pad with respect to a normal direction of the mounting surface of the module substrate.

16. The semiconductor module according to claim 2, wherein
the second electronic circuit includes at least one switching transistor,
the first electronic circuit includes a controlled circuit whose operating state is switched by on and off of the switching transistor, and
the inter-member connection wire connects the switching transistor and the controlled circuit to each other.

17. The semiconductor module according to claim 16, wherein
the first electronic circuit includes an impedance matching circuit including a plurality of passive elements, and
one of the switching transistors is connected to at least one of the plurality of passive elements.

18. The semiconductor module according to claim 16, wherein
the first electronic circuit includes a protection circuit including a plurality of diodes connected in series, and
one of the switching transistors is connected in parallel to some of the plurality of diodes configuring the protection circuit.

19. A semiconductor device comprising:
a first member that includes a semiconductor substrate including a compound semiconductor, and a first electronic circuit on an upper surface which is one surface of the semiconductor substrate;
a second member that is bonded to the upper surface of the first member, and includes a semiconductor layer configured of a single semiconductor thinner than the semiconductor substrate and a second electronic circuit on the semiconductor layer;
a first pad that is on the first member and is connected to the first electronic circuit;
a second pad that is on the second member and is connected to the second electronic circuit; and
an inter-member connection wire configured of a conductor film that is on the first member and the second member and connects the first electronic circuit and the second electronic circuit to each other.
